(19) United States
(12) Patent Application Publication
(10) Pub. No.: US 2013/0284247 A1
(43) Pub. Date: Oct. 31, 2013

(54) P-N JUNCTION SEMICONDUCTOR DEVICE WITH PHOTOVOLTAIC PROPERTIES

(71) Applicant: NUSOLA, INC., (US)

(72) Inventors: Jose Briceno, Tokyo-to (JP); Koji Matsumaru, Nagaoka-Shi (JP)

(21) Appl. No.: 13/844,596

(22) Filed: Mar. 15, 2013

Related U.S. Application Data
(60) Provisional application No. 61/722,693, filed on Nov. 5, 2012.
(60) Provisional application No. 61/655,449, filed on Jun. 4, 2012.
(60) Provisional application No. 61/619,410, filed on Apr. 2, 2012.
(60) Provisional application No. 61/715,280, filed on Oct. 17, 2012.

(51) Int. Cl. H01L 31/0224

(52) U.S. Cl. CPC H01L 31/022466; H01L 31/022483
USPC 136/255; 136/252; 136/261; 438/98

(57) ABSTRACT

A material is manufactured from a transformative process of heating a structure comprising a transparent conductive oxide disposed over a semiconductor material. The heating process causes a p-type dopant from the semiconductor material diffuses into the transparent conductive oxide, and causes the semiconductor material to transform into an intrinsic semiconductor layer over a bulk layer. The material manufactured exhibits photovoltaic properties because the layers formed during the transformative process create a p-i-n or a p-n junction having a band-gap difference between the top layer and the bulk layer.

### CROSS-REFERENCE TO RELATED APPLICATIONS

This application claims the benefit of U.S. Provisional Application No. 61/715,280, entitled “P-N Junction Semiconductor Device With Photovoltaic Properties,” filed Oct. 17, 2012 (Ref. No. P11), U.S. Provisional Application No. 61/722,693, entitled “Photovoltaic Cell and Methods of Manufacture,” filed on Nov. 5, 2012 (Ref. No. P3), U.S. Provisional Application No. 61/655,449, entitled “Structure For Creating Ohmic Contact In Semiconductor Devices And Methods for Manufacture,” filed on Jun. 4, 2012 (Ref. No. P4), and U.S. Provisional Application No. 61/619,410, entitled “Single-Piece Photovoltaic Structure,” filed on Apr. 2, 2012 (Ref. No. P2), the entireties of which are incorporated by reference as if fully set forth herein.

This application is related to copending U.S. application Ser. No. 13/______, “Single-Piece Photovoltaic Structure,” filed on even date herewith (Ref. No. P2), U.S. application Ser. No. 13/______, “Photovoltaic Cell And Methods For Manufacture,” filed on even date herewith (Ref. No. P3), and U.S. application Ser. No. 13/______, “Structure For Creating Ohmic Contact In Semiconductor Devices And Methods For Manufacture,” filed on even date herewith (Ref. No. P4), the entirety of which is incorporated by reference as if fully set forth herein.

### FIELD OF THE INVENTION

The present invention relates to photovoltaic devices, and in particular, a photovoltaic device structure with improved photovoltaic properties and a simplified method of manufacture.

### BACKGROUND OF THE INVENTION

The approaches described in this section are approaches that could be pursued, but not necessarily approaches that have been previously conceived or pursued. Therefore, unless otherwise indicated, it should not be assumed that any of the approaches described in this section qualify as prior art merely by virtue of their inclusion in this section.

Legacy solar cell manufacturing process consists of many manufacturing steps that make this process costly. In many cases, the use of toxic materials is also part of the manufacturing process. It is desirable to manufacture a photovoltaic device with fewer manufacturing steps and less use of toxic materials.

### BRIEF SUMMARY OF PREFERRED EMBODIMENTS OF THE INVENTION

Preferred embodiments of the invention provide a novel semiconductor device with photovoltaic properties. Embodiments of the device are manufactured using a thermal annealing process from a single piece of single-crystal silicon, without the need of texturing, and doping, and provide the advantage of low manufacturing cost. In one example of a preferred embodiment, the thermal annealing process to manufacture a photovoltaic device includes placing an electrode, such as a zinc oxide (ZnO) electrode, over a n-type silicon wafer substrate, such as one doped with phosphorus. After the annealing process is completed, the manufactured device exhibits photovoltaic properties.

During the annealing process, the phosphorus contained in the n-type silicon diffuses into the interface between the silicon wafer and the ZnO electrode of the device due to the heating. The phosphorus diffusion renders the ZnO as a p-type layer, which also behaves as a p-type semiconductor. In some embodiments, the phosphorus diffusion also reduces the phosphorus concentration in a gradient, and creates an intrinsic semiconductor layer between the n-type silicon substrate and the p-type ZnO electrode layer, creating a p-i-n junction with photovoltaic properties.

### BRIEF DESCRIPTION OF THE DRAWINGS

Preferred embodiments of the present invention are illustrated by way of example, and not by way of limitation, in the figures of the accompanying drawings and in which like reference numerals refer to similar elements and in which:

FIG. 1 is a block diagram that illustrates a structure of a semiconductor device with photovoltaic properties, according to embodiments of the invention.

FIG. 2 is a flow diagram that illustrates an example process for manufacturing the structure shown in FIG. 1 according to embodiments of the invention.

### DETAILED DESCRIPTION OF PREFERRED EMBODIMENTS OF THE INVENTION

In the following description numerous specific details have been set forth to provide a more thorough understanding of embodiments of the present invention. It will be appreciated however, by one skilled in the art, that embodiments of the invention may be practiced without such specific details or with different implementations for such details. Additionally some well known structures have not been shown in detail to avoid unnecessarily obscuring the present invention.

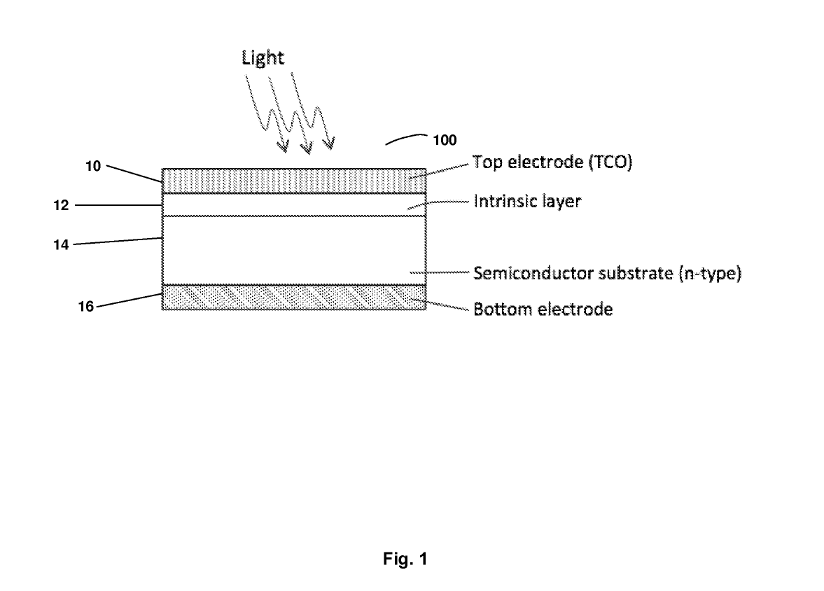

In accordance with preferred embodiments of the invention, FIG. 1 is a block diagram that illustrates a structure of a semiconductor device with photovoltaic properties, according to embodiments of the invention.

In some embodiments, structure 100 is formed from a single-crystal n-type semiconductor substrate 14 treated with a dopant element, top electrode 10 composed of a transparent conductive oxide (TCO), and bottom electrode 16. Intrinsic semiconductor layer 12 is a resulting feature of submitting the semiconductor substrate 14 to a thermal annealing process.

Semiconductor substrate 14 comprises any one of Silicon (Si), Germanium (Ge), or any other group IV semiconductor. In some embodiments, the wafer thickness of semiconductor substrate 14 is 1 μm or thicker. The dopant element comprises any one of Phosphorus (P), Nitrogen (N), Antimony (Sb), Arsenic (As) or any other element of group V. In some embodiments, the phosphorus content is above 0.01 ppb. In some embodiments, the amount of phosphorus found in a standard n-type silicon wafer as a result of standard n-type silicon fabrication is sufficient phosphorus content for use as semiconductor substrate 14. In some embodiments, a higher concentration of phosphorus in semiconductor substrate 14 can be obtained by employing methods ion implantation and chemical diffusion to add phosphorus to semiconductor substrate 14.

Top electrode 10 comprises any one of Zinc Oxide (ZnO), Nickel Oxide (NiO), Cadmium Oxide (CdO), Wurtzite, Halite, or other binary transparent conductive oxide. In some embodiments, top electrode 10 has any one of a wurtzite crystal structure or zinc blende crystal structure. Top electrode 10 is transformed into a p-type semiconductor by placing top electrode 10 onto semiconductor substrate 14, and subjecting the assembly to a thermal annealing process. Through the process, the dopant element from the semiconductor substrate 14 diffuses into the top electrode 10. Through the process, intrinsic layer 12 is formed from semiconductor substrate 14 in the interface between semiconductor substrate 14 and top electrode 10. Table 1 illustrates the possible device components for semiconductor substrate 14, dopant, and top electrode 10. In a preferred embodiment, the thickness of top electrode 10 must be less than 100 nm to allow dopant element diffusion from semiconductor substrate 14. Top TCO layer may be fabricated by a deposition process, including but not limited to chemical vapor deposition (CVD), pulsed laser deposition (PLD), molecular beam epitaxy (MBE), reactive physical vapor deposition (or reactive sputtering), or any other similar method.

TABLE 1
Device construction possibilities

Semiconductor substrate (n-type)

| Semiconductor | Dopant | TCO |
|---|---|---|
| Silicon (Si) | Phosphorous (P) | ZnO |
| Germanium (Ge) | Nitrogen (N) | NiO |
| Or any other | Antimony (Sb) | CdO |
| element of | Arsenic (As) | Or Wurtzite, Halite |
| group IV | Or any other | or other binary |
| | element of | transparent |
| | group V | conductive oxide |

Bottom electrode 16 comprises a metal such as aluminum (Al), gold (Au), copper (Cu), silver (Ag), indium (In), cadmium (Cd), thallium (Tl), tin (Sn), tungsten (W), platinum (Pt), gallium (Ga), zinc (Zn), titanium (Ti), and nickel (Ni), and metallic alloys. Bottom electrode is applied to the assembly to form structure 100 by deposition of the metal onto semiconductor substrate 14, including by processes such as screen painting, ink jet printing, physical vapor deposition (e.g., sputtering). An alternative method for applying bottom electrode includes the method described in copending U.S. application Ser. No. 13/______ (TBD), entitled “Structure For Creating Ohmic Contact In Semiconductor Devices And Methods For Manufacture,” filed 2012, claiming priority to U.S. Application No. 61/655,449, filed Jun. 4, 2012, the contents of both of which are hereby incorporated by reference as if fully set forth herein.

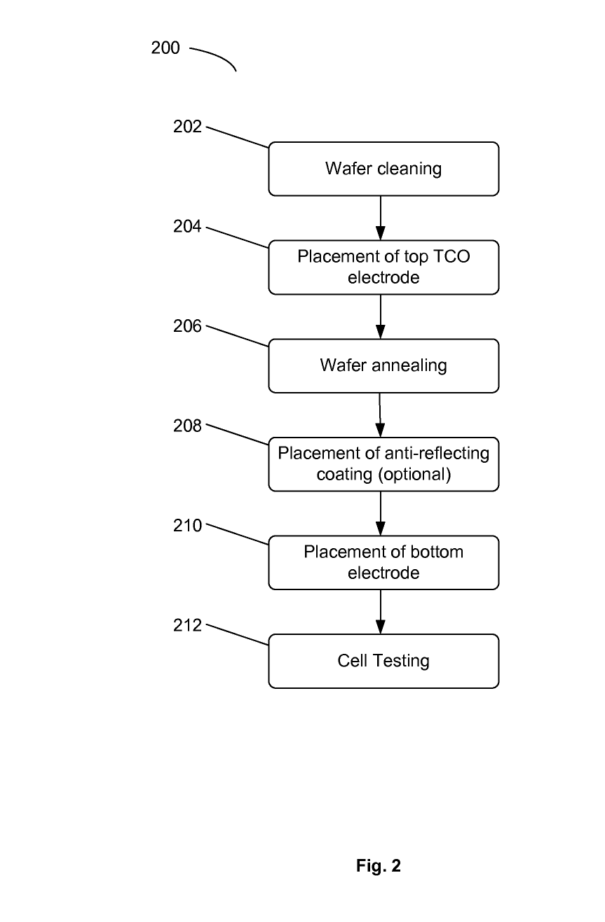

Standard manufacturing process of this photo-voltaic cell, as described in FIG. 2, consists of cleaning, and an annealing process, followed by placement of the top and bottom electrode to complete the device. Placement of top TCO electrode is performed before wafer annealing. In addition, and for photo-voltaic applications, an optional anti-reflecting coating may be placed on the top surface (on top of TCO layer) in order to improve light absorption and therefore cell performance.

In accordance with preferred embodiments of the invention, FIG. 2 is a flow diagram that illustrates process 200 for manufacturing structure 100. While the example describes the method with reference to using silicon as the semiconductor substrate and ZnO as the top electrode, it is understood by one of skill in the art that the method can be used with full scope of the components previously described.

With reference to FIG. 2, at step 202 wafer cleaning is performed. In some embodiments, silicon wafers are cleaned by dipping the wafers into a solution of hydrofluoric acid, followed by water cleaning and air drying. This process mainly targets the removal of the natural oxide film formed on the wafer surface.

At step 204, placement of top electrode is performed. In some embodiments, a ZnO electrode is placed on top of phosphorus-doped n-type silicon wafer, for example by sputtering ZnO onto the silicon wafer.

At step 206, wafer annealing is performed. In some embodiments, silicon wafers are submitted to an annealing process. The parameters in which the annealing is performed are show in Table 2 below.

TABLE 2
Wafer annealing conditions:

| Parameter | Value | Typical case |
|---|---|---|
| Annealing temperature (K) | 500 to 1700 | 1500 |
| Annealing time (min) | 1 to 600 | 30 |
| Atmosphere | Vacuum, Argon, | Argon |
| | Nitrogen, or | |
| | other inert gas | |
| Treatment pressure (atm) | Up to 1 | 2 × 10⁻⁴ |

Wafer annealing may be performed in diverse methods, such as, convection heated annealing, infrared annealing, laser annealing, induction heated annealing, microwave annealing.

During the annealing process, the phosphorus contained in the n-type silicon diffuses to the interface between silicon and ZnO of the device, as a result the heating process. Then this phosphorus would diffuse into the top ZnO layer, rendering this ZnO as p-type layer, which also behaves as a p-type semiconductor.

The reduction in phosphorus concentration in the silicon substrate will result in an intrinsic layer created between the Silicon substrate and the top ZnO layer. As a result, a n-i-p junction device is created in just one annealing process to fabricate this device, which also has photo-voltaic properties.

At step 208, in some embodiments, placement of an anti-reflecting coating over the top electrode occurs to improve performance of the photovoltaic cell.

At step 210, placement of bottom electrode occurs. In some embodiments, an aluminum layer is preferred for the bottom electrode. Thickness of the bottom electrode may vary between 1 and 800 microns, typically about 500 microns. A bottom aluminum electrode may be fabricated by physical vapor deposition (sputtering), screen printing, ink-jet printing or other standard printing or metal deposition techniques.

In some embodiments, the bottom electrode forms an ohmic contact with the semiconductor substrate. In general, it is not trivial to manufacture an ohmic contact electrode, such as the bottom electrode, just by using metals elements. In some cases, the use of precious metals such as gold, silver, or platinum creates a Shottcky barrier between the metal and the semiconductor, therefore increasing contact resistivity. This may also be observed for other metals such as aluminum and copper, which are also metals normally used in electrical contacts. In order to ensure a good ohmic contact between the substrate semiconductor and back electrode, additional steps are needed. In some embodiments, techniques such as surface polishing, abrasion, or texturing, before depositing the ohmic contact metal are used.

In other embodiments, the placement of a buffer layer before depositing the metal contact as electrode is used to create an ohmic contact between the bottom electrode and the semiconductor substrate. One example of such a buffer is amorphous silicon carbide, as described in copending U.S. application Ser. No. 13/______ (TBD), entitled “Structure For Creating Ohmic Contact In Semiconductor Devices And Methods For Manufacture,” filed 2012, claiming priority to U.S. Application No. 61/655,449, filed Jun. 4, 2012, the contents of both of which are hereby incorporated by reference as if fully set forth herein.

Preferred embodiments of the invention provide numerous advantages over legacy photovoltaic device manufacturing approaches. The manufacturing process is simpler and costs less. In photovoltaic applications, superior photon usage is attributable to the transparency of the TCO electrode. Further, compared to silicon, which is widely used in legacy solar cells, all TCO as oxides are commonly stable, and offer chemical resistance, a high resistance to radiation, and higher physical resistance. Further, preferred embodiments provide a wide-bandgap joint device. As solar cell performance is governed in part by the band-gap of its components, in particular the bandgap at the p-n junction, the wide bandgap of 1.1 eV for silicon and up to 3.4 eV for ZnO provides improved photovoltaic properties.

Other features, aspects and objects of the invention can be obtained from a review of the figures and the claims. It is to be understood that other embodiments of the invention can be developed and fall within the spirit and scope of the invention and claims.

The foregoing description of preferred embodiments of the present invention has been provided for the purposes of illustration and description. It is not intended to be exhaustive or to limit the invention to the precise forms disclosed. Various additions, deletions and modifications are contemplated as being within its scope. The scope of the invention is, therefore, indicated by the appended claims rather than the foregoing description. Further, all changes which may fall within the meaning and range of equivalency of the claims and elements and features thereof are to be embraced within their scope.

What is claimed is:

1. A photovoltaic material comprising:
a bulk layer of semiconductor material;
an intermediate layer provided over the bulk layer; and
a p-type top layer,
whereby the bulk layer, the intermediate layer, and the p-type top layer are created by a transformative process on a single-piece semiconductor material having disposed a transparent conductive oxide layer, the single-piece semiconductor material having an impurity.

2. The photovoltaic material of claim 1, wherein the transformative process is caused by performing the steps of:
forming the transparent conductive oxide layer over the single-piece semiconductor material;
exposing of a top surface of the single-piece semiconductor material to an energy source, whereby the energy source causes heating of a portion of the single-piece semiconductor material; and
ceasing exposure of the top surface of the single-piece semiconductor material to the energy source,
whereby the exposing step and the ceasing step cause the impurity in the single-piece semiconductor to diffuse into the transparent conductive oxide layer to transform into the p-type layer, and cause the single-piece semiconductor material to transform into a material comprising the intermediate layer over the bulk layer.

3. The photovoltaic material of claim 2, wherein the heating occurs at a temperature between 500 K and 1700 K.

4. The photovoltaic material of claim 2, wherein the steps of exposing and ceasing occurs in a vacuum.

5. The photovoltaic material of claim 2, wherein the heating of the portion occurs for a duration of 1 to 600 minutes.

6. The photovoltaic material of claim 1, whereby the intermediate layer is substantially equivalent to intrinsic semiconductor.

7. The photovoltaic material of claim 1, wherein the transparent conductive oxide comprises any one of ZnO, NiO, CdO, Wurtzite, Halite, or other binary transparent conductive oxide.

8. The photovoltaic material of claim 1, wherein the single-crystal semiconductor material comprises Si, Ge, or other group IV semiconductor.

9. The photovoltaic material of claim 1, wherein the impurity comprises a dopant, including P, N, Sb, As, or other group V element.

10. The photovoltaic material of claim 1, wherein the band gap of the bulk layer is smaller than the band gap the top layer.

11. The photovoltaic material of claim 1, wherein the top layer, the intermediate layer, and the bulk layer form any one of a p-i-n junction, or a p-n junction.

12. The photovoltaic material of claim 1, wherein the photovoltaic material produces photovoltaic effects when exposed to light.

13. A photovoltaic device using the photovoltaic material according to claim 1, the photovoltaic device comprising:
the photovoltaic material; and
a bottom electrode provided under the photovoltaic material.

14. A method for manufacturing a photovoltaic material, comprising a transformative process that is caused by performing the steps of:
forming a transparent conductive oxide layer over a single-piece semiconductor material;
exposing of a top surface of the single-piece semiconductor material to an energy source, whereby the energy source causes heating of a portion of the single-piece semiconductor material; and
ceasing exposure of the top surface of the single-piece semiconductor material to the energy source,
whereby the exposing step and the ceasing step cause an impurity in the single-piece semiconductor to diffuse into the transparent conductive oxide layer to transform into a p-type layer, and cause the single-piece semiconductor material to transform into a material comprising an intermediate layer over a bulk layer.

15. The method of claim 14, wherein the heating occurs at a temperature between 500 K and 1700 K.

16. The method of claim 14, wherein the steps of exposing and ceasing occurs in a vacuum.

17. The method of claim 14, wherein the heating of the portion occurs for a duration of 1 to 600 minutes.

18. The method of claim 14, whereby the intermediate layer is substantially equivalent to intrinsic semiconductor.

19. The method of claim 14, wherein the transparent conductive oxide comprises any one of ZnO, NiO, CdO, Wurtzite, Halite, or other binary transparent conductive oxide.

20. The method of claim 14, wherein the single-crystal semiconductor material comprises Si, Ge, or other group IV semiconductor.

21. The method of claim 14, wherein the impurity comprises a dopant, including P, N, Sb, As, or other group V element.

22. The method of claim 14, wherein the band gap of the bulk layer is smaller than the band gap the top layer.

23. The method of claim 14, wherein the top layer, the intermediate layer, and the bulk layer form any one of a p-i-n junction, or a p-n junction.

24. The method of claim 14, wherein the photovoltaic material produces photovoltaic effects when exposed to light.
